(19) United States
(12) Patent Application Publication
(10) Pub. No.: US 2026/0123417 A1
(43) Pub. Date: Apr. 30, 2026

(54) ELECTRONIC PACKAGE AND ELECTRONIC STRUCTURE

(71) Applicant: SILICONWARE PRECISION INDUSTRIES CO., LTD., Taichung City (TW)

(72) Inventors: Dai-Fei LI, Taichung City (TW); Chuan-Shun LI, Taichung City (TW); Wen-Yu TENG, Taichung City (TW); Liang-Yi HUNG, Taichung City (TW)

(73) Assignee: SILICONWARE PRECISION INDUSTRIES CO., LTD., Taichung City (TW)

(21) Appl. No.: 19/080,015

(22) Filed: Mar. 14, 2025

(30) Foreign Application Priority Data
Oct. 24, 2024 (TW) 113140617

(51) Int. Cl. H01L 23/373; H01L 23/00; H01L 23/367

(52) U.S. Cl. CPC H10W 40/257; H10W 40/22; H10W 40/255; H10W 72/322; H10W 72/325; H10W 72/351; H10W 72/352; H10W 72/877; H10W 74/15; H10W 90/724; H10W 90/734

(57) ABSTRACT

Provided are an electronic package and an electronic structure. The electronic package includes a carrier, an electronic component disposed on the carrier, a heat dissipation member connected to the electronic component through a thermal interface material, a backside metal layer disposed on the electronic component and connected to the thermal interface material, and a nanowire array metal layer disposed between the thermal interface material and the backside metal layer. Therefore, a displacement of the thermal interface material relative to the backside metal layer is limited by a rough surface of the nanowire array metal layer. As such, a migration of the thermal interface material and a resulting poor bonding between the heat dissipation member and the electronic component, which affect a heat dissipation efficiency of the electronic package, can be prevented.

### BACKGROUND

### 1. Technical Field

The present disclosure relates to a semiconductor device, and more particularly, to an electronic package and electronic structure.

### 2. Description of Related Art

As the demand for functionality and processing speed of electronic products increases, it is required for semiconductor chips, which are the core components of electronic products, to have higher density electronic circuits and elements. Therefore, a greater amount of heat energy the will be generated during operation of by the semiconductor chips. Furthermore, the conventional encapsulant encapsulating the semiconductor chip is a poor heat transfer material with a thermal conductivity of only 0.8 W/mk (that is, the heat dissipation is inefficiency). Therefore, the heat generated by the semiconductor chips will damage the semiconductor chips and cause product reliability issues if the heat cannot be effectively dissipated.

Accordingly, in order to quickly dissipate heat energy to the outside, the industry usually disposes heat sinks or heat spreaders in the semiconductor package. The heat sinks are coupled to the back of the semiconductor chip to dissipate the heat generated by the semiconductor chip through the heat sink.

FIG. 1 is a schematic cross-sectional view of a conventional semiconductor package 1. The semiconductor package 1 includes a package substrate 11, a semiconductor chip 12 mounted on an upper side of the packaged substrate 11 in a flip-chip manner, and a heat sink 13. The heat sink 13 is made of copper, and the semiconductor chip 12 is made of silicon. In order to improve the bonding effect and heat dissipation effect between the heat sink 13 and the semiconductor chip 12, the industry usually forms a backside metal layer (BSM) 15 and a thermal interface material (TIM) 14 on the back of the semiconductor chip 12.

Specifically, when the thermal interface material 14 with a low melting point is formed on a back of the semiconductor chip 12, the backside metal layer 15 is required to be formed on the back of the semiconductor chip 12. However, after the semiconductor chip 12 being formed with the thermal interface material 14 with the low melting point, the semiconductor chip 12 is easily affected by machine movements before entering a high-temperature process, causing the thermal interface material 14 with the low melting point to slip or overflow out of a back edge of the semiconductor chip 12 (as shown in FIG. 1). Therefore, the thermal interface material 14 between the heat sink 13 and the semiconductor chip 12 is insufficient, resulting in a poor heat dissipation effect, thereby a heat dissipation capability of the semiconductor package 1 is reduced.

To this end, the conventional solution in the industry is to adhere the backside metal layer and the thermal interface material by a polymer glue. However, reactions of metal ions during the soldering process between the thermal interface material with the low melting point and the backside metal layer will be hindered by the polymer glue, holes and cracks are formed in the soldering interface, and thus the heat dissipation effect is reduced.

Therefore, there is a need for a solution that addresses the aforementioned shortcomings in the prior art.

### SUMMARY

In view of the aforementioned shortcomings of the prior art, the present disclosure provides an electronic package, which comprises: a carrier; an electronic component disposed on the carrier; a heat dissipation member covering the electronic component; a thermal interface material for the heat dissipation member being connected to the electronic component by the thermal interface material; a backside metal layer disposed on the electronic component; and a nanowire array metal layer disposed between the thermal interface material and the backside metal layer and coupled to the thermal interface material.

The present disclosure also provides an electronic structure, which comprises: an electronic component; a backside metal layer disposed on the electronic component; and a nanowire array metal layer disposed on the backside metal layer.

In the aforementioned electronic package and electronic structure, the electronic component has an active surface and an inactive surface opposite to the active surface, and the active surface is electrically connected to the carrier through a plurality of conductive bumps in a flip-chip manner.

In the aforementioned electronic package and electronic structure, the heat dissipation member has a top sheet and a support leg, and one end of the support leg is coupled to the top sheet, and the other end of the support leg is disposed on the carrier.

In the aforementioned electronic package and electronic structure, the thermal interface material is a metal layer with a low melting point.

In the aforementioned electronic package and electronic structure, the thermal interface material is indium or gallium.

In the aforementioned electronic package and electronic structure, the backside metal layer is one selected from the group consisting of aluminum, titanium, nickel, vanadium and gold.

In the aforementioned electronic package and electronic structure, the backside metal layer is a structure of multiple metal layers, and the nanowire array metal layer is formed on an outermost metal layer of the structure of multiple metal layers by electroplating.

In the aforementioned electronic package and electronic structure, a material of the nanowire array metal layer is one of gold (Au), silver (Ag), copper (Cu), and nickel (Ni).

In the aforementioned electronic package and electronic structure, a surface of the backside metal layer is formed with a rough structure by the nanowire array metal layer.

In the aforementioned electronic package and electronic structure, the thermal interface material is deformed and sunk into a nano array of the nanowire array metal layer for the nanowire array metal layer being coupled to the thermal interface material.

Through implementation of the present disclosure, the nanowire array metal layer is mainly disposed between the thermal interface material and the backside metal layer, which allows the surface of the backside metal layer to be formed with the rough structure to increase friction, and thus poor bonding between the heat dissipation member and the electronic component due to migration of the thermal interface material during subsequent manufacturing processes and affected heat dissipation efficiency of the electronic package caused thereby can be avoided. At the same time, the thermal interface material can be sunk into the nanowire array metal layer and firmly fixed, allowing the thermal interface material to be effectively coupled to the nanowire array metal layer and to be closely adhered to the surface of electronic component, which improves the heat dissipation efficiency of electronic package.

### BRIEF DESCRIPTION OF THE DRAWINGS

FIG. 1 is a schematic cross-sectional view of a conventional semiconductor package.

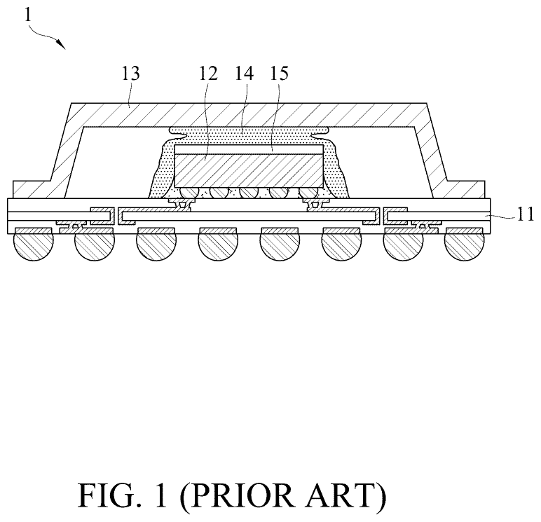

FIG. 2 is a schematic cross-sectional view of an electronic package of the present disclosure.

FIG. 3 is a partial cross-sectional schematic diagram of an electronic structure of the present disclosure.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

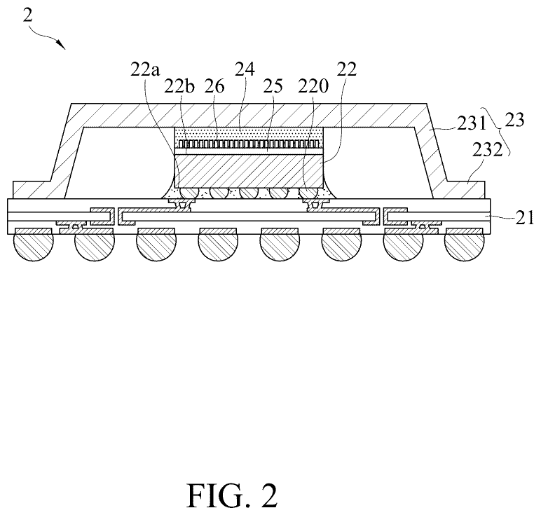

FIG. 2 is a schematic cross-sectional view of an electronic package 2 of the present disclosure. The electronic package 2 includes a carrier 21; an electronic component 22 disposed on and electrically connected to the carrier 21; a heat dissipation member 23 covering the electronic component 22; a thermal interface material 24 for connecting the heat dissipation member 23 to the electronic component 22 by the thermal interface material 24; a backside metal layer 25 disposed on the electronic component 22 and connected to the thermal interface material 24; and a nanowire array metal layer 26 disposed between the thermal interface material 24 and the backside metal layer 25 and coupled to the thermal interface material 24.

The carrier 21 is, for example, a package substrate having a core layer and a circuit structure or a coreless circuit structure including a dielectric layer and a circuit layer (such as a redistribution layer). In addition, the carrier 21 can also be a lead frame, a silicon interposer, a wafer, or other board bodies with metal routing, but the present disclosure is not limited to as such.

The electronic component 22 is mounted on the carrier 21 and electrically connected to the circuit layer. The electronic component 22 may be an active element, a passive element, a package structure, or a combination thereof. The active element may be an application processor (AP) used in mobile device such as mobile phone or other semiconductor chips such as computing chips, while the passive element may be a resistor, capacitor, inductor, etc. In one embodiment, the electronic component 22 is a semiconductor chip, which has an active surface 22a and an inactive surface 22b opposite to the active surface 22a. The active surface 22a is electrically connected to the carrier 21 through a plurality of conductive bumps 220 in a flip-chip manner.

The heat dissipation member 23 is, for example, a heat sink, a heat dissipation lid, or other elements with equivalent functions. In one embodiment, the heat dissipation member 23 has a top sheet 231 and support legs 232. One end of each of the support legs 232 is coupled to the top sheet 231, the other end of each of the support legs 232 is disposed on the carrier 21, and thus a bottom surface of the top sheet 231 is opposite to the inactive surface 22b of the electronic component 22. In addition, the heat dissipation member 23 is made of copper metal.

A thermal interface material 24 is further disposed between the inactive surface 22b of the electronic component 22 and the bottom surface of the top sheet 231 of the heat dissipation member 23, and a heat generated by the electronic component 22 can be more efficiently transferred to the heat dissipation member 23 and then effuse to environment. In one embodiment, the thermal interface material 24 is a metal layer with a low melting point, such as indium (In) or gallium (Ga).

The backside metal layer 25 is disposed on the electronic component 22 and connected to the thermal interface material 24. The backside metal layer 25 can be a structure of multiple metal layers, and for example one from the group consisting of aluminum (Al), titanium (Ti), nickel (Ni), vanadium (V) and gold (Au).

The nanowire array metal layer 26 is disposed between the thermal interface material 24 and the backside metal layer 25 and is coupled to the thermal interface material 24. The nanowire array metal layer 26 is formed on an outermost metal layer of the structure of multiple metal layers of the backside metal layer 25 by electroplating. The nanowire array metal layer 26 is made of a material such as gold (Au), silver (Ag), copper (Cu) or nickel (Ni), which can form a rough structure on a surface of the backside metal layer 25 to increase friction, thereby the thermal interface material 24 (for example, an indium metal layer with a low melting point) is less likely to slide during the manufacturing process. Further, since the thermal interface material 24 with the low melting point is a soft metal, an external force can be applied to the thermal interface material 24 when the thermal interface material 24 is formed on the nanowire array metal layer 26 on the surface of the backside metal layer 25 during the manufacturing process, the thermal interface material 24 with the low melting point is deformed and sunk into a nano array of the nanowire array metal layer 26. Therefore, the thermal interface material 24 can be firmly fixed without affecting the soldering quality, and thus the nanowire array metal layer 26 is effectively coupled to the thermal interface material 24.

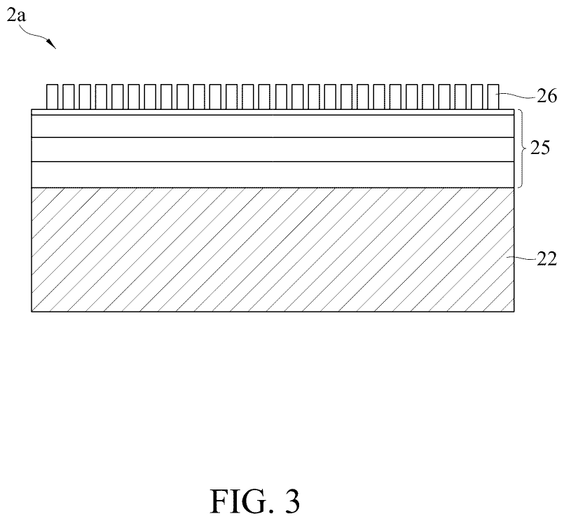

Referring to FIG. 3, the present disclosure further discloses an electronic structure 2a including an electronic component 22, a backside metal layer 25 and a nanowire array metal layer 26.

The backside metal layer 25 is disposed on the electronic component 22 and can be a structure of multiple metal layers.

The nanowire array metal layer 26 is formed on an outermost metal layer of a structure of multiple metal layers of the backside metal layer 25 by electroplating, which can form a rough structure on the surface of the backside metal layer 25 to increase friction for coupling to the thermal interface material.

In view of the above, in the electronic package and electronic structure, the nanowire array metal layer is disposed between the thermal interface material and the backside metal layer, which allows the surface of the backside metal layer to be formed with the rough structure to increase friction, and thus poor coupling between the heat dissipation member and the electronic component due to migration of the thermal interface material during subsequent manufacturing processes and affected heat dissipation efficiency of the electronic package caused thereby can be avoided. At the same time, the thermal interface material can be sunk into the nanowire array metal layer and firmly fixed, allowing the thermal interface material to be effectively coupled to the nanowire array metal layer and to be closely adhered to the surface of electronic component, which improves the heat dissipation efficiency of electronic packages. Furthermore, adding new development processes and materials or the purchasing machines is not required for the aforementioned structures. Existing materials and current processes and machines can be used to solve the technical problems in the industry, and no large additional costs is incurred.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier;
an electronic component disposed on the carrier;
a heat dissipation member covering the electronic component;
a thermal interface material for disposing the heat dissipation member onto the electronic component via the thermal interface material;
a backside metal layer formed on the electronic component; and
a nanowire array metal layer disposed between the thermal interface material and the backside metal layer and coupled to the thermal interface material.

2. The electronic package of claim 1, wherein the electronic component has an active surface and an inactive surface opposite to the active surface, and the active surface is electrically connected to the carrier through a plurality of conductive bumps in a flip-chip manner.

3. The electronic package of claim 1, wherein the heat dissipation member has a top sheet and a support leg, and one end of the support leg is coupled to the top sheet, and the other end of the support leg is disposed on the carrier.

4. The electronic package of claim 1, wherein the thermal interface material is a metal layer with a low melting point.

5. The electronic package of claim 1, wherein the thermal interface material is indium or gallium.

6. The electronic package of claim 1, wherein the backside metal layer is one selected from the group consisting of aluminum, titanium, nickel, vanadium and gold.

7. The electronic package of claim 1, wherein the backside metal layer is a structure of multiple metal layers, and the nanowire array metal layer is formed on an outermost metal layer of the structure of multiple metal layers.

8. The electronic package of claim 1, wherein a material of the nanowire array metal layer is one of gold, silver, copper, and nickel.

9. The electronic package of claim 1, wherein a surface of the backside metal layer is formed with a rough structure by the nanowire array metal layer.

10. The electronic package of claim 1, wherein the thermal interface material is deformed and sunk into a nano array of the nanowire array metal layer for the nanowire array metal layer being coupled to the nanowire array metal layer.

11. An electronic structure, comprising:
an electronic component;
a backside metal layer disposed on the electronic component; and
a nanowire array metal layer disposed on the backside metal layer.

12. The electronic structure of claim 11, wherein the nanowire array metal layer is coupled to the thermal interface material, and the thermal interface material is a metal layer with a low melting point.

13. The electronic structure of claim 12, wherein the thermal interface material is indium or gallium.

14. The electronic structure of claim 12, wherein the thermal interface material is deformed and sunk into a nano array of the nanowire array metal layer for the nanowire array metal layer being coupled to the nanowire array metal layer.

15. The electronic structure of claim 11, wherein the backside metal layer is one selected from the group consisting of aluminum, titanium, nickel, vanadium and gold.

16. The electronic structure of claim 11, wherein the nanowire array metal layer is formed on an outermost metal layer of a structure of multiple metal layers.

17. The electronic structure of claim 11, wherein a material of the nanowire array metal layer is one of gold, silver, copper, and nickel.

18. The electronic structure of claim 11, wherein a surface of the backside metal layer is formed with a rough structure by the nanowire array metal layer.
